(19) United States
(12) Patent Application Publication
(10) Pub. No.: US 2023/0163152 A1
(43) Pub. Date: May 25, 2023

(54) BACKSIDE ILLUMINATED IMAGE SENSOR AND METHOD OF MANUFACTURING THE SAME

(71) Applicant: DB HITEK CO., LTD., Seoul (KR)

(72) Inventor: Chang Hun HAN, Gyeonggi-do (KR)

(21) Appl. No.: 17/993,358

(22) Filed: Nov. 23, 2022

(30) Foreign Application Priority Data
Nov. 25, 2021 (KR) 10-2021-0164892

(51) Int. Cl. H01L 27/146

(52) U.S. Cl. CPC H01L 27/1464; H01L 27/14687; H01L 27/14632; H01L 27/1463

(57) ABSTRACT

A backside illuminated image sensor includes a substrate having a frontside surface and a backside surface, a charge accumulation region disposed in the substrate, and a light isolation pattern surrounding at least a portion of the charge accumulation region and comprising a metal material. The substrate has a trench extending from the backside surface toward the frontside surface, and the light isolation pattern is disposed in the trench.

### CROSS-REFERENCE TO RELATED APPLICATION

This application claims the priority benefit of Korean Patent Application No. 10-2021-0164892, filed on Nov. 25, 2021, and all the benefits accruing therefrom under 35 U.S.C. § 119, the contents of which are incorporated by reference in their entirety.

### TECHNICAL FIELD

The present disclosure relates to a backside illuminated image sensor and a method of manufacturing the same. More specifically, the present disclosure relates to a backside illuminated image sensor including a color filter layer and a micro lens array formed on a backside surface of a substrate, and a method of manufacturing the same.

### BACKGROUND

In general, an image sensor is a semiconductor device that converts an optical image into electrical signals, and may be classified or categorized as a Charge Coupled Device (CCD) or a Complementary Metal Oxide Semiconductor (CMOS) Image Sensor (CIS).

The CIS includes unit pixels, each including a photodiode and MOS transistors. The CIS sequentially detects the electrical signals of the unit pixels using a switching method, thereby forming an image. The CIS may be classified as either a frontside illuminated image sensor or a backside illuminated image sensor.

The backside illuminated image sensor may include pixel regions formed in a substrate, transistors formed on a frontside surface of the substrate, an insulating layer formed on the transistors, bonding pads on the insulating layer, an anti-reflective layer formed on a backside surface of the substrate, a light-blocking pattern formed on the anti-reflective layer, a planarization layer formed on the light-blocking pattern, a color filter layer formed on the planarization layer, and a micro lens array formed on the color filter layer.

The light-blocking pattern may have openings corresponding to the pixel regions, and may be used to reduce crosstalk of the back-illuminated image sensor. However, when the size of the pixel regions is reduced in order to increase the resolution of the back-illuminated image sensor, the crosstalk of the back-illuminated image sensor may be increased.

### SUMMARY

The present disclosure provides a backside illuminated image sensor capable of reducing the crosstalk and a method of manufacturing the backside illuminated image sensor.

In accordance with an aspect of the present disclosure, a backside illuminated image sensor may include a substrate having a frontside surface and a backside surface, a charge accumulation region disposed in the substrate, and a light isolation pattern configured to surround at least a portion of the charge accumulation region and comprising a metal material.

In accordance with some embodiments of the present disclosure, the backside illuminated image sensor may further include a light blocking pattern disposed on the backside surface of the substrate and having an opening corresponding to the charge accumulation region.

In accordance with some embodiments of the present disclosure, the light isolation pattern may be made of the same material as the light blocking pattern.

In accordance with some embodiments of the present disclosure, the light isolation pattern may extend from the light blocking pattern toward the frontside surface of the substrate.

In accordance with some embodiments of the present disclosure, the substrate may have a trench extending from the backside surface toward the frontside surface, and the light isolation pattern may be disposed in the trench.

In accordance with some embodiments of the present disclosure, the backside illuminated image sensor may further include an anti-reflective layer disposed on the backside surface of the substrate. In such case, the anti-reflective layer may include first portions disposed between the light isolation pattern and inner surfaces of the trench.

In accordance with some embodiments of the present disclosure, the backside illuminated image sensor may further include a field isolation region disposed in a frontside surface portion of the substrate, an insulating layer disposed on the frontside surface of the substrate and a frontside surface of the field isolation region, and a bonding pad disposed on a frontside surface of the insulating layer.

In accordance with some embodiments of the present disclosure, a first through-hole exposing a portion of a backside surface of the field isolation region may be formed through the substrate, an anti-reflective layer may be disposed on the backside surface of the substrate, and the anti-reflective layer may include a second portion disposed on an inner side surface of the first through-hole and a third portion disposed on the portion of the backside surface of the field isolation region.

In accordance with some embodiments of the present disclosure, a second bonding pad may be disposed on the anti-reflective layer, a second through-hole may be formed through the second bonding pad, the third portion of the anti-reflective layer, the field isolation region, and the insulating layer to expose a portion of a backside surface of the bonding pad, and a third bonding pad may be disposed on the second bonding pad, an inner side surface of the second through-hole, and the portion of the backside surface of the bonding pad.

In accordance with some embodiments of the present disclosure, a fourth bonding pad may be disposed on the third bonding pad, the third bonding pad may be made of the same material as the second bonding pad, and the fourth bonding pad may be made of the same material as the bonding pad.

In accordance with another aspect of the present disclosure, a method of manufacturing a backside illuminated image sensor may include forming a charge accumulation region in a substrate, and forming a light isolation pattern comprising a metal material in the substrate to surround at least a portion of the charge accumulation region.

In accordance with some embodiments of the present disclosure, forming the light isolation pattern may include forming a trench extending from a backside surface of the substrate toward a frontside surface of the substrate and surrounding the at least a portion of the charge accumulation region. In such case, the light isolation pattern may be formed in the trench.

In accordance with some embodiments of the present disclosure, the method may further include forming an anti-reflective layer on the backside surface of the substrate and inner surfaces of the trench. In such case, the light isolation pattern may be formed in the trench by forming a metal layer on the anti-reflective layer so that the trench is buried.

In accordance with some embodiments of the present disclosure, the method may further include forming a field isolation region in a frontside surface portion of the substrate, forming an insulating layer on a frontside surface of the substrate and a frontside surface of the field isolation region, and forming a bonding pad on a frontside surface of the insulating layer.

In accordance with some embodiments of the present disclosure, the method may further include forming a first through-hole through the substrate to expose a portion of a backside surface of the field isolation region, forming an anti-reflective layer on a backside surface of the substrate, an inner side surface of the first through-hole, and the portion of the backside surface of the field isolation region, forming a first metal layer on the anti-reflective layer, forming a second through-hole through the first metal layer, the anti-reflective layer, the field isolation region, and the insulating layer to expose a portion of a backside surface of the bonding pad, forming a second metal layer on the first metal layer, an inner side surface of the second through-hole, and the portion of the backside surface of the bonding pad, patterning the second metal layer to form a third bonding pad electrically connected to the bonding pad, and patterning the first metal layer to form a second bonding pad between the anti-reflective layer and the third bonding pad.

In accordance with some embodiments of the present disclosure, forming the light isolation pattern may include forming a trench extending from the backside surface of the substrate toward the frontside surface of the substrate and surrounding the at least a portion of the charge accumulation region. In such case, a portion of the anti-reflective layer may be formed on inner surfaces of the trench, and the first metal layer may be formed to fill the trench, whereby the light isolation pattern is formed in the trench.

In accordance with some embodiments of the present disclosure, the method may further include forming a light blocking pattern having an opening corresponding to the charge accumulation region on the anti-reflective layer.

In accordance with some embodiments of the present disclosure, the light blocking pattern may be formed on the light isolation pattern by patterning the first metal layer.

In accordance with some embodiments of the present disclosure, the method may further include forming a first through-hole through the substrate to expose a portion of a backside surface of the field isolation region, forming an anti-reflective layer on a backside surface of the substrate, an inner side surface of the first through-hole, and the portion of the backside surface of the field isolation region, forming a first metal layer on the anti-reflective layer, forming a second through-hole through the first metal layer, the anti-reflective layer, the field isolation region, and the insulating layer to expose a portion of a backside surface of the bonding pad, forming a second metal layer on the first metal layer, an inner side surface of the second through-hole, and the portion of the backside surface of the bonding pad, forming a third metal layer on the second metal layer, patterning the third metal layer to form a fourth bonding pad on the second metal layer, patterning the second metal layer to form a third bonding pad on the first metal layer, the inner side surface of the second through-hole, and the portion of the backside surface of the bonding pad, and patterning the first metal layer to form a second bonding pad between the anti-reflective layer and the third bonding pad.

In accordance with some embodiments of the present disclosure, the bonding pad may be made of the same material as the fourth bonding pad, and the second bonding pad may be made of the same material as the third bonding pad.

In accordance with the embodiments of the present disclosure as described above, the light isolation pattern may be formed to surround at least a portion of the charge accumulation region. As a result, light leakage to adjacent charge accumulation regions may be sufficiently reduced, and thus the crosstalk of the backside illuminated image sensor may be significantly reduced.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating a backside illuminated image sensor in accordance with an embodiment of the present disclosure;

FIG. 2 is a schematic cross-sectional view illustrating a backside illuminated image sensor in accordance with another embodiment of the present disclosure;

FIGS. 3 to 13 are schematic cross-sectional views illustrating a method of manufacturing the backside illuminated image sensor as shown in FIG. 1; and

FIGS. 14 and 15 are schematic cross-sectional views illustrating a method of manufacturing the backside illuminated image sensor as shown in FIG. 2.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

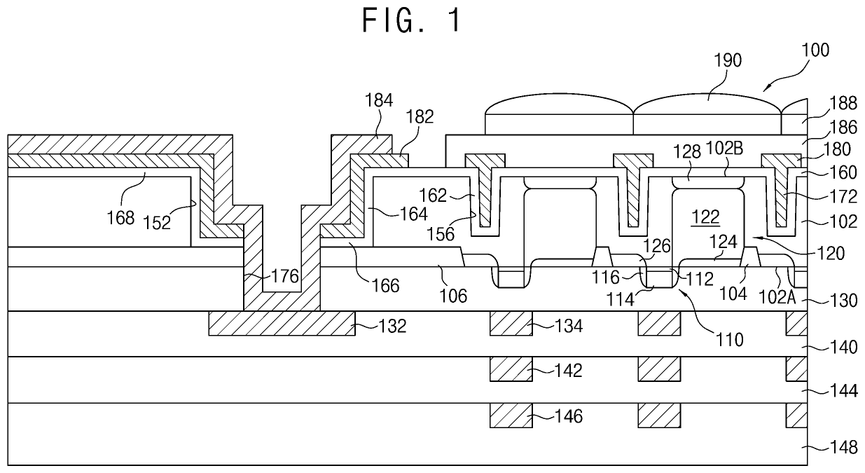

FIG. 1 is a schematic cross-sectional view illustrating a backside illuminated image sensor in accordance with an embodiment of the present disclosure.

Referring to FIG. 1, a backside illuminated image sensor 100, in accordance with an embodiment of the present disclosure, may include a substrate 102 in which pixel regions 120 are formed. Each of the pixel regions 120 may include a charge accumulation region 122 in which charges generated by the incident light are accumulated. The substrate 102 may have a first conductivity type, and the charge accumulation region 122 may have a second conductivity type. The charge accumulation region 122 may be disposed in the substrate 102, and a floating diffusion region 126 may be disposed in a frontside surface portion of the substrate 102 to be spaced apart from the charge accumulation region 122. The floating diffusion region 126 may have the same conductivity type as the charge accumulation region 122. For example, a P-type substrate may be used as the substrate 102, and N-type impurity diffusion regions serving as the charge accumulation region 122 and the floating diffusion region 126 may be formed in the P-type substrate 102. As another example, the substrate 102 may include a P-type epitaxial layer. In such case, the charge accumulation region 122 and the floating diffusion region 126 may be formed in the P-type epitaxial layer.

A transfer gate structure 110 may be disposed on a channel region between the charge accumulation region 122 and the floating diffusion region 126 to transfer the charges accumulated in the charge accumulation region 122 to the floating diffusion region 126. The transfer gate structure 110 may include a gate insulating layer 112 disposed on a frontside surface 102A of the substrate 102, a gate electrode 114 disposed on the gate insulating layer 112, and a gate spacer 116 disposed on side surfaces of the gate electrode 114. Further, though not shown in FIG. 1, the backside illuminated image sensor 100 may include a reset transistor, a source follower transistor, and a select transistor disposed on the frontside surface 102A of the substrate 102 and electrically connected with the floating diffusion region 126.

Alternatively, if the backside illuminated image sensor 100 is a 3T (or fewer than three transistors) layout, the transfer gate structure 110 may be used as a reset gate structure, and the floating diffusion region 126 may be used as an active region for connecting the charge accumulation region 122 with a reset circuitry.

Each of the pixel regions 120 may include a frontside pinning layer 124 disposed between the frontside surface 102A of the substrate 102 and the charge accumulation region 122. Further, each of the pixel regions 120 may include a backside pinning layer 128 disposed between a backside surface 102B of the substrate 102 and the charge accumulation region 132. The frontside and backside pinning layers 124 and 128 may have the first conductivity type. For example, p-type impurity diffusion regions may be used as the frontside and backside pinning layers 124 and 128.

The backside illuminated image sensor 100 may include a field isolation region 106 formed on a frontside surface portion of the substrate 102, an insulating layer 130 formed on the frontside surface 102A of the substrate 102 and a frontside surface of the field isolation region 106, and a bonding pad 132 formed on a frontside surface of the insulating layer 130. A first wiring layer 134 electrically connected to the pixel regions 120 may be formed on the front surface of the insulating layer 130, and the bonding pad 132 and the first wiring layer 134 may be formed of the same material. For example, the bonding pad 132 and the first wiring layer 134 may be made of aluminum.

Further, a second insulating layer 140 may be formed on the frontside surface of the insulating layer 130, the bonding pad 132 and the first wiring layer 134, and a second wiring layer 142 may be disposed on the second insulating layer 140. A third insulating layer 144 may be formed on the second insulating layer 140 and the second wiring layer 142, and a third wiring layer 146 may be disposed on the third insulating layer 144. A passivation layer 148 may be formed on the third insulating layer 144 and the third wiring layer 146.

An anti-reflective layer 160 may be formed on the backside surface 102B of the substrate 102. For example, the anti-reflective layer 160 may include a metal oxide layer formed on the backside surface 102B of the substrate 102 and a silicon oxide layer formed on the metal oxide layer. The metal oxide layer may function as a negative fixed charge layer and may include aluminum oxide (Al₂O₃), hafnium oxide (HfO₂), hafnium aluminum oxide (HfAlO), aluminum oxynitride (AlON), hafnium oxynitride (HfON) or hafnium aluminum oxynitride (HfAlON). In such case, negative charges of the negative fixed charge layer may form a negatively charged shallow minority carrier rich region, i.e., a hole accumulation region, in a backside surface portion of the substrate 102, and thus, a dark current of the backside illuminated image sensor 100 may be reduced. As an example, an aluminum oxide layer may be formed on the backside surface 102B of the substrate 102, a hafnium oxide layer may be formed on the aluminum oxide layer, and a silicon oxide layer may be formed on the hafnium oxide layer.

Alternatively, when the charge accumulation region 122 has the first conductivity type, that is, an n-type substrate is used as the substrate 102 and the charge accumulation region 122 include p-type impurities, the metal oxide layer may function as a positive fixed charge layer and include zirconium oxide (ZrO₂), hafnium silicon oxide (HfSiO₂), hafnium silicon oxynitride (HfSiON) or silicon nitride (Si₃N₄). In such case, the positive fixed charge layer may form an electron accumulation region in a backside surface portion of the substrate 102.

In accordance with an embodiment of the present disclosure, the backside illuminated image sensor 100 may include a light isolation pattern 172 formed to surround at least a portion of the charge accumulation region 122 and made of a metal material. For example, the substrate 102 may have a trench 156 extending from the backside surface 102B of the substrate 102 toward the frontside surface 102A of the substrate 102 and surrounding at least a portion of the charge accumulation region 122, and the light isolation pattern 172 may be disposed in the trench 156. In particular, the anti-reflective layer 160 may include first portions 162 formed between the light isolation pattern 172 and inner surfaces of the trench 156. Specifically, the anti-reflective layer 160 may be formed on the backside surface 102B of the substrate 102 and the inner surfaces of the trench 156, and the light isolation pattern 172 may be formed on the first portions 162 of the anti-reflective layer 160 so as to fill the trench 156.

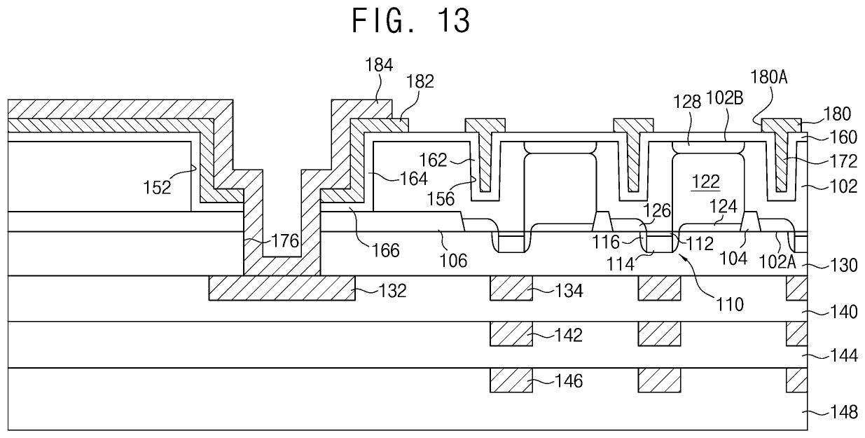

Further, a light-blocking pattern 180 may be formed on the anti-reflective layer 160. For example, the light-blocking pattern 180 may have an opening 180A (refer to FIG. 13) corresponding to the charge accumulation region 122, and the light isolation pattern 172 may extend from the light-blocking pattern 180 toward the frontside surface 102A of the substrate 102. In particular, the light isolation pattern 172 and the light-blocking pattern 180 may be made of the same material, and may be simultaneously formed through a chemical vapor deposition process. For example, the light isolation pattern 172 and the light-blocking pattern 180 may be made of tungsten.

A planarization layer 186 may be formed on the anti-reflective layer 160 and the light-blocking pattern 180. For example, the planarization layer 186 may be made of silicon oxide or a thermosetting resin, and a color filter layer 188 and a micro lens array 190 may be sequentially formed on the planarization layer 186.

In accordance with an embodiment of the present disclosure, the light isolation pattern 172 may prevent the light from leaking to adjacent pixel regions 120, and thus the crosstalk of the backside-illuminated image sensor 100 may be significantly reduced. For example, in order to reduce the crosstalk of the backside-illuminated image sensor 100, the light isolation pattern 170 may have a height of about 50% to about 90% of a thickness of the substrate 102.

Further, in accordance with an embodiment of the present disclosure, a first through-hole 152 exposing a portion of a backside surface of the field isolation region 106 may be formed through the substrate 102. In such case, the anti-reflective layer 160 may include a second portion 164 formed on an inner side surface of the first through-hole 152 and a third portion 166 formed on the exposed portion of the backside surface of the field isolation region 106.

A second bonding pad 182 may be formed on the anti-reflective layer 160. Specifically, the second bonding pad 182 may be formed on the second portion 164 and the third portion 166 of the anti-reflective layer 160, and a fourth portion 168 of the anti-reflective layer 160 formed on a portion of the backside surface 102B of the substrate 102 adjacent to the first through-hole 152. In particular, the second bonding pad 182 may be made of the same material as the light isolation pattern 172 and the light-blocking pattern 180, and may be formed simultaneously with the light isolation pattern 172 and the light blocking-pattern 180.

A second through-hole 176 exposing a portion of a backside surface of the bonding pad 132 may be formed through the second bonding pad 182, the third portion 166 of the anti-reflective layer 160, the field isolation region 106 and the insulating layer 130. In addition, a third bonding pad 184 may be formed on the second bonding pad 182, an inner side surface of the second through-hole 176, and the exposed portion of the backside surface of the bonding pad 132. In this case, the third bonding pad 184 may be made of a material different from that of the second bonding pad 182. For example, the third bonding pad 184 may be made of aluminum. In particular, the third bonding pad 184 may be made of the same material as the bonding pad 132, so that the electrical resistance between the bonding pad 132 and the third bonding pad 184 may be reduced.

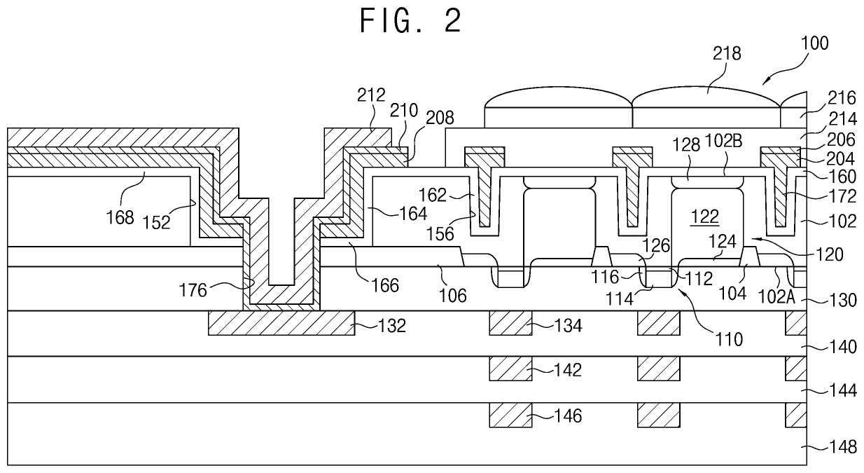

FIG. 2 is a schematic cross-sectional view illustrating a backside illuminated image sensor in accordance with another embodiment of the present disclosure.

Referring to FIG. 2, in accordance with another embodiment of the present disclosure, a second bonding pad 208 may be formed on the second portion 164 and the third portion 166 of the anti-reflective layer 160, and a fourth portion 168 of the anti-reflective layer 160 formed on a portion of the backside surface 102B of the substrate 102 adjacent to the first through-hole 152. A second through-hole 176 exposing a portion of a backside surface of the bonding pad 132 may be formed through the second bonding pad 208, the third portion 166 of the anti-reflective layer 160, the field isolation region 106 and the insulating layer 130. A third bonding pad 210 may be formed on the second bonding pad 208, an inner side surface of the second through-hole 176, and the exposed portion of the backside surface of the bonding pad 132, and a fourth bonding pad 212 may be formed on the third bonding pad 210. In this case, the third bonding pad 210 may be made of the same material as the second bonding pad 208, and the fourth bonding pad 212 may be made of a material different from that of the second bonding pad 208. For example, the third bonding pad 210 may be made of tungsten, and the fourth bonding pad 212 may be made of aluminum. In particular, the third bonding pad 210 may be formed to improve the step coverage of the fourth bonding pad 212.

In accordance with another embodiment of the present disclosure, a light-blocking pattern 204 may be formed on the light isolation pattern 172. Further, a second light-blocking pattern 206 may be formed on the light-blocking pattern 204. The second light-blocking pattern 206 may be made of the same material as the light-blocking pattern 204. In addition, the second light-blocking pattern 206 may be made of the same material as the third bonding pad 210, and may be formed simultaneously with the third bonding pad 210.

Further, a planarization layer 214 may be formed on the anti-reflective layer 160, the light-blocking pattern 204 and the second light-blocking pattern 206. For example, the planarization layer 214 may be made of silicon oxide or a thermosetting resin, and a color filter layer 216 and a micro lens array 218 may be sequentially formed on the planarization layer 214.

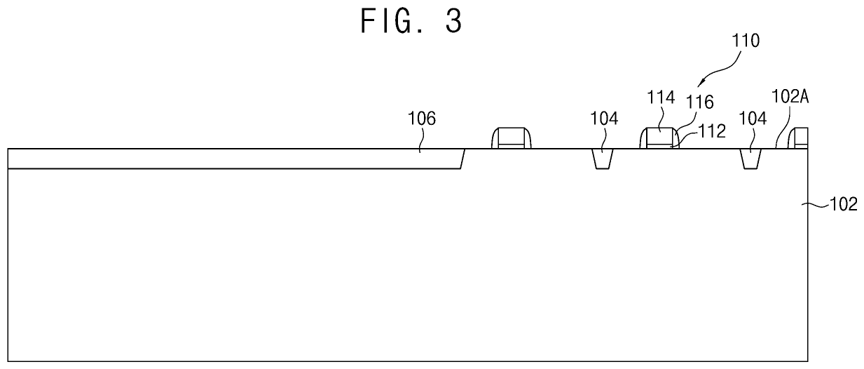

FIGS. 3 to 13 are schematic cross-sectional views illustrating a method of manufacturing the backside illuminated image sensor as shown in FIG. 1.

Referring to FIG. 3, device isolation regions 104 may be formed in frontside surface portions of a substrate 102 to define active regions of a backside illuminated image sensor 100. Further, a field isolation region 106 may be formed in a pad region of the substrate 102 together with the device isolation regions 104. For example, the substrate 102 may have a first conductivity type. For example, a p-type substrate may be used as the substrate 102. Alternatively, the substrate 102 may include a bulk silicon substrate and a p-type epitaxial layer formed on the bulk silicon substrate. The device isolation regions 104 and the field isolation region 106 may be made of silicon oxide and may be formed by a shallow trench isolation (STI) process.

After forming the device isolation regions 104 and the field isolation region 106, transfer gate structures 110 may be formed on a frontside surface 102A of the substrate 102. Each of the transfer gate structures 110 may include a gate insulating layer 112, a gate electrode 114 formed on the gate insulating layer 112 and a gate spacer 116 formed on side surfaces of the gate electrode 114. Further, though not shown in figures, reset gate structures, source follower gate structures and select gate structures may be simultaneously formed with the transfer gate structures 110 on the frontside surface 102A of the substrate 102.

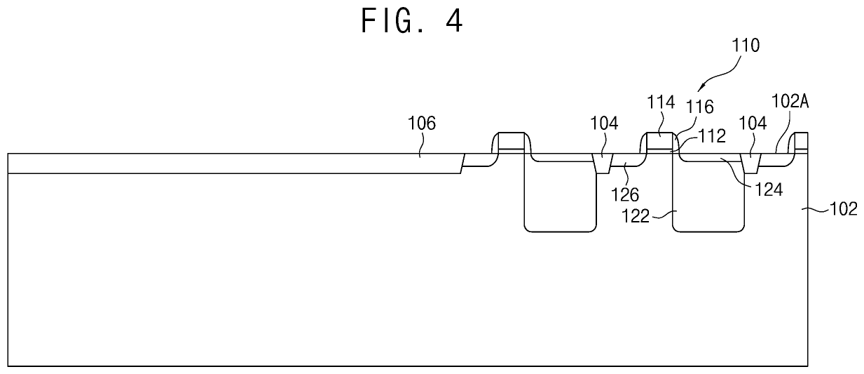

Referring to FIG. 4, charge accumulation regions 122 may be formed in the substrate 102. Specifically, charge accumulation regions 122 having a second conductivity type may be formed in the active regions of the substrate 102. For example, n-type charge accumulation regions 122 may be formed in the p-type substrate 102. The n-type charge accumulation regions 122 may be n-type impurity diffusion regions formed by an ion implantation process.

Then, frontside pinning layers 124 having the first conductivity type may be formed between the frontside surface 102A of the substrate 102 and the charge accumulation regions 122. For example, p-type frontside pinning layers 124 may be formed between the frontside surface 102A of the substrate 102 and the n-type charge accumulation regions 122 by an ion implantation process. The p-type frontside pinning layers 124 may be p-type impurity diffusion regions. The n-type charge accumulation regions 122 and the p-type frontside pinning layers 124 may be activated by a subsequent rapid heat treatment process.

Further, floating diffusion regions 126 having the second conductivity type may be formed in frontside surface portions of the substrate 102 to be spaced apart from the charge accumulation regions 122. For example, the floating diffusion regions 126 may be n-type high concentration impurity regions, which may be formed by an ion implantation process. At this time, the transfer gate structures 110 may be arranged on channel regions between the charge accumulation regions 122 and the floating diffusion regions 126.

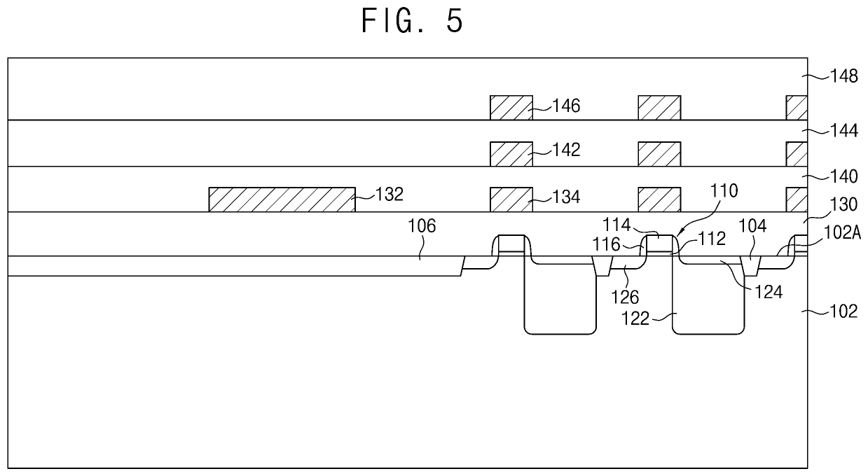

Referring to FIG. 5, an insulating layer 130 made of an insulating material such as silicon oxide may be formed on the frontside surface 102A of the substrate 102 and a frontside surface the field isolation region 106. Further, a bonding pad 132 and a first wiring layer 134 may be formed on a frontside surface of the insulating layer 130. For example, the bonding pad 132 and the first wiring layer 134 may be formed by forming a metal layer such as an aluminum layer on the insulating layer 130 and patterning the metal layer.

Further, a second insulating layer 140 may be formed on the insulating layer 130, the bonding pad 132 and the first wiring layer 134, and a second wiring layer 142 may be formed on the second insulating layer 140. A third insulating layer 144 may be formed on the second insulating layer 140 and the second wiring layer 142, and a third wiring layer 146 may be formed on the third insulating layer 144. A passivation layer 148 may be formed on the third insulating layer 144 and the third wiring layer 146. The first, second and third wiring layers 134, 142 and 146 may be electrically connected with the pixel regions 120, and the bonding pad 132 may be electrically connected with the first, second and third wiring layers 134, 142 and 146.

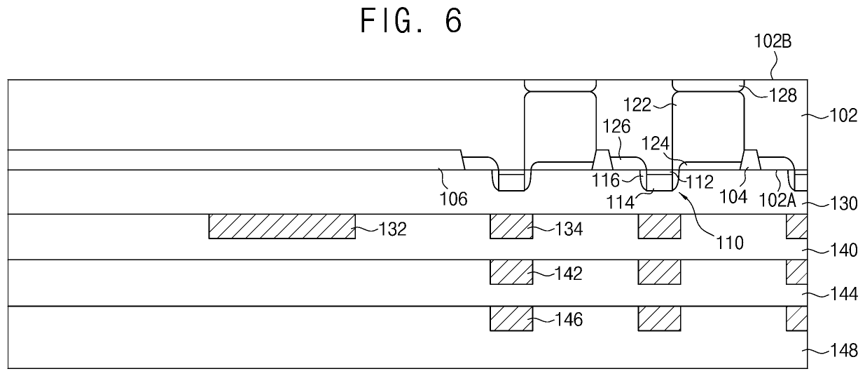

Referring to FIG. 6, a back-grinding process or a chemical and mechanical polishing process may be performed in order to reduce a thickness of the substrate 102. Further, backside pinning layers 128 having the first conductivity type may be formed between a backside surface 102B of the substrate 102 and the charge accumulation regions 122. For example, as shown in FIG. 6, after inverting the substrate 102 so that the backside surface 102B of the substrate 102 faces upward, p-type backside pinning layers 128 may be formed between the backside surface 102B of the substrate 102 and the charge accumulation regions 122 through an ion implantation process. In such case, the p-type backside pinning layers 128 may be activated through a laser annealing process.

Alternatively, the backside pinning layers 128 may be formed prior to the charge accumulation regions 122. For example, after forming the backside pinning layers 128, the charge accumulation regions 122 may be formed on the backside pinning layers 128, and the frontside pinning layers 124 may then be formed on the charge accumulation regions 122. In such case, the backside pinning layers 128 may be activated by the rapid heat treatment process along with the charge accumulation regions 122 and the frontside pinning layers 124. Further, the back-grinding process may be performed such that the backside pinning layers 128 are exposed.

As another example, when the substrate 102 includes a bulk silicon substrate and a p-type epitaxial layer formed on the bulk silicon substrate, the charge accumulation regions 122 and the frontside and backside pinning layers 124 and 128 may be formed in the p-type epitaxial layer, and the bulk silicon substrate may be removed by the back-grinding process.

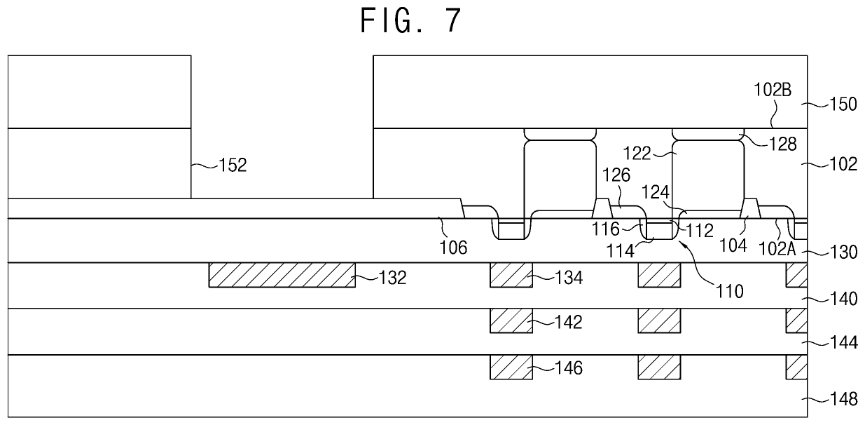

Referring to FIG. 7, the substrate 102 may be partially removed to form a first through-hole 152 corresponding to the bonding pad 132. For example, a first photoresist pattern 150 exposing a portion of the backside surface 102B of the substrate 102 corresponding to the bonding pad 132 may be formed on the backside surface 102B of the substrate 102, and the first through-hole 152 may be formed through the substrate 102 to expose a portion of a backside surface of the field isolation region 106 by performing an anisotropic etching process using the first photoresist pattern 150 as an etching mask. The first photoresist pattern 150 may be removed by an ashing or stripping process after forming the first through-hole 152.

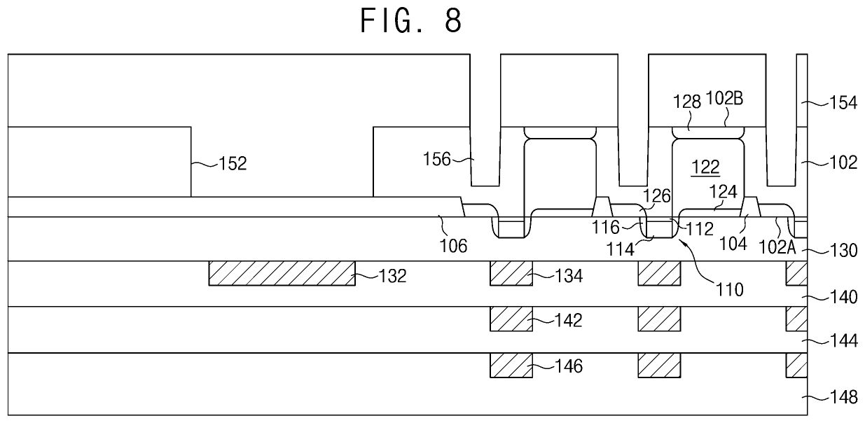

Referring to FIG. 8, a trench 156 surrounding at least a portion of the charge accumulation region 122 may be formed by partially removing the substrate 102. For example, a second photoresist pattern 154 exposing portions of the backside surface 102B of the substrate 102 corresponding to the trenches 156 may be formed on the backside surface 102B of the substrate 102, and the trenches 156 surrounding the charge accumulation regions 122 may be formed by performing an anisotropic etching process using the second photoresist pattern 154 as an etching mask. In this case, the trenches 156 may have a lattice shape, and the second photoresist pattern 154 may be removed by an ashing or stripping process after forming the trenches 156.

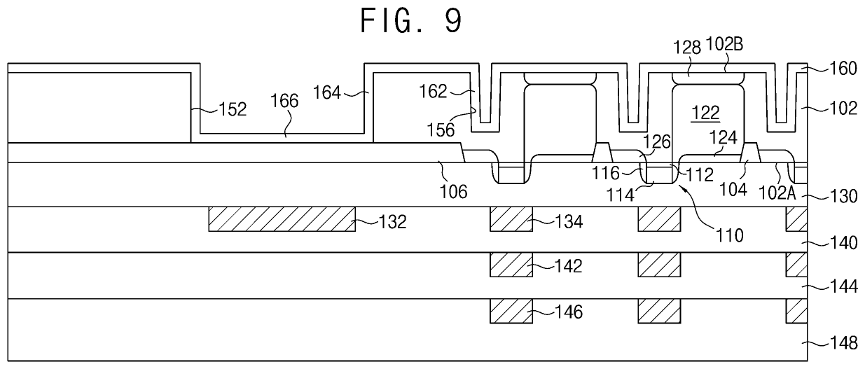

Referring to FIG. 9, an anti-reflective layer 160 may be formed on the backside surface 102B of the substrate 102. In particular, the anti-reflective layer 160 may be formed to have a uniform thickness on the backside surface 102B of the substrate 102, an inner side surface of the first through-hole 152, the portion of the backside surface of the field isolation region 106 exposed by the first through-hole 152, and inner surfaces of the trenches 156. The anti-reflective layer 160 may include a metal oxide layer formed on the backside surface 102B of the substrate 102 and a silicon oxide layer formed on the metal oxide layer.

Further, the anti-reflective layer 160 may include first portions 162 formed in the trenches 156, a second portion 164 formed on the inner side surface of the first through-hole 152, and a third portion 166 formed on the portion of the backside surface of the field isolation region 106. For example, an aluminum oxide layer may be formed on the backside surface 102B of the substrate 102, a hafnium oxide layer may be formed on the aluminum oxide layer, and a silicon oxide layer may be formed on the hafnium oxide layer. The aluminum oxide layer and the hafnium oxide layer may be formed by an atomic layer deposition process, and the silicon oxide layer may be formed by a chemical vapor deposition process.

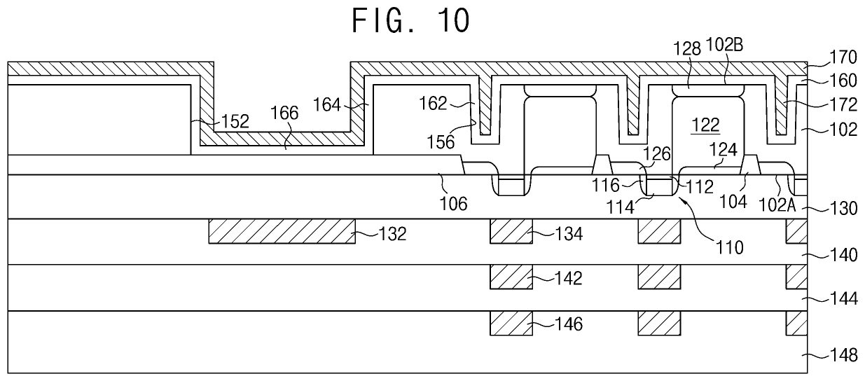

Referring to FIG. 10, a first metal layer 170 may be formed on the anti-reflective layer 160. In particular, the first metal layer 170 may be formed to sufficiently fill the trenches 156, and thus, light isolation patterns 172 surrounding the charge accumulation regions 122 may be formed in the trenches 156. For example, a tungsten layer 170 may be formed on the anti-reflective layer 160 through a chemical vapor deposition process, and thus, light isolation patterns 170 made of tungsten may be formed in the trenches 156.

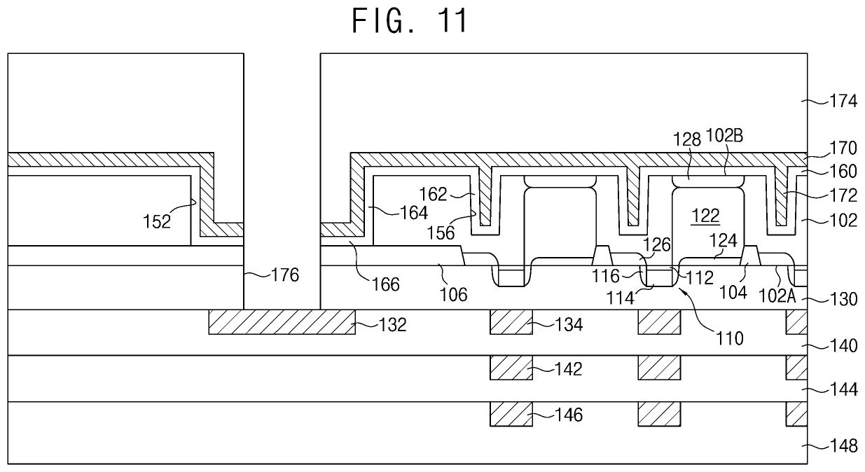

Referring to FIG. 11, a second through-hole 176 exposing a portion of a backside surface of the bonding pad 132 may be formed. For example, after forming a third photoresist pattern 174 exposing a portion of the first metal layer 170 formed on the third portion 166 of the anti-reflective layer 160, as shown in FIG. 11, the second through-hole 176 may be formed by performing an anisotropic etching process using the third photoresist pattern 174 as an etching mask. Specifically, the second through-hole 176 may expose the portion of the backside surface of the bonding pad 132 through the first metal layer 170, the third portion 166 of the anti-reflective layer 160, the field isolation region 106, and the insulating layer 130. The third photoresist pattern 174 may be removed by an ashing or stripping process after forming the second through-hole 176.

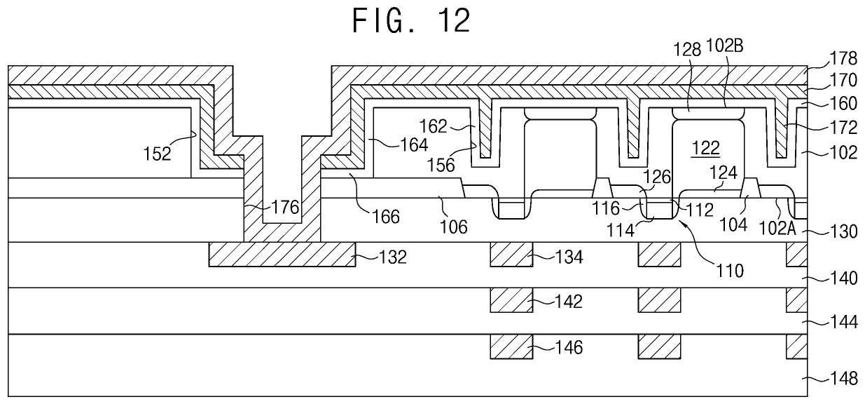

Referring to FIG. 12, a second metal layer 178 may be formed on the first metal layer 170, an inner side surface of the second through-hole 176, and the exposed portion of the backside surface of the bonding pad 132. For example, an aluminum layer 178 may be formed to a uniform thickness on the first metal layer 170, the inner side surface of the second through-hole 176, and the exposed portion of the backside surface of the bonding pad 132 through a sputtering process.

Referring to FIG. 13, a third bonding pad 184 electrically connected to the bonding pad 132 may be formed on the first metal layer 170 by patterning the second metal layer 178. Then, a light-blocking pattern 180 and a second bonding pad 182 may be formed by patterning the first metal layer 170. The light-blocking pattern 180 may be positioned on the light isolation pattern 172. Accordingly, the light-blocking pattern 180 may have openings 180A corresponding to the charge accumulation regions 122. Further, the second bonding pad 182 may be formed on the anti-reflective layer 160, and the third bonding pad 184 may be formed on the second bonding pad 182, the inner side surface of the second through-hole 176, and the exposed portion of the backside surface of the bonding pad 132.

Referring again to FIG. 1, a planarization layer 186 made of an insulating material such as silicon oxide or a thermosetting resin may be formed on the anti-reflective layer 160 and the light-blocking pattern 180, and then, a color filter layer 188 and a microlens array 190 may be sequentially formed on the planarization layer 186.

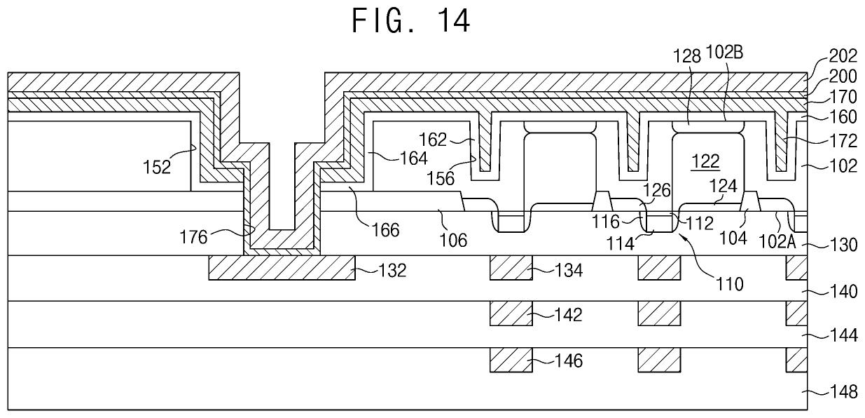

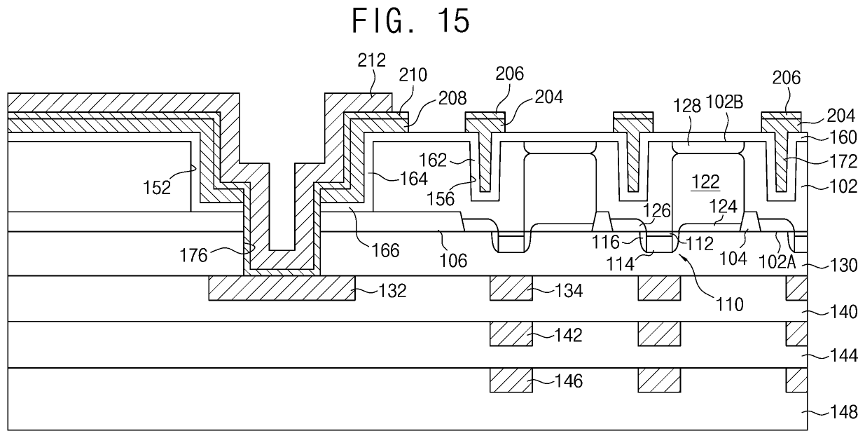

FIGS. 14 and 15 are schematic cross-sectional views illustrating a method of manufacturing the backside illuminated image sensor as shown in FIG. 2.

Referring to FIG. 14, a second metal layer 200 may be formed on the first metal layer 170, the inner side surface of the second through-hole 176, and the exposed portion of the backside surface of the bonding pad 132, and then, a third metal layer 202 may be formed on the second metal layer 200. For example, a second tungsten layer 200 may be formed to a uniform thickness on the first metal layer 170, the inner side surface of the second through-hole 176, and the exposed portion of the backside surface of the bonding pad 132 through a chemical vapor deposition process. Then, an aluminum layer 202 may be formed to a uniform thickness on the second tungsten layer 200 through a sputtering process.

Referring to FIG. 15, a fourth bonding pad 212 may be formed on the second metal layer 200 by patterning the third metal layer 202. Then, a second light-blocking pattern 206, a light-blocking pattern 204, a third bonding pad 210, and a second bonding pad 208 may be formed by patterning the second metal layer 200 and the first metal layer 170. The light-blocking pattern 204 and the second light-blocking pattern 206 may be positioned on the light isolation pattern 172. The second bonding pad 208 may be formed on the anti-reflective layer 160. The third bonding pad 210 may be formed on the second bonding pad 208, the inner side surface of the second through-hole 176, and the portion of the backside surface of the bonding pad 132. The fourth bonding pad 212 may be formed on the third bonding pad 210.

Referring again to FIG. 2, a planarization layer 214 made of an insulating material such as silicon oxide or a thermosetting resin may be formed on the anti-reflective layer 160 and the second light-blocking pattern 206, and then, a color filter layer 216 and a microlens array 218 may be sequentially formed on the planarization layer 214.

In accordance with the embodiments of the present disclosure as described above, the light isolation pattern 172 may be formed to surround at least a portion of the charge accumulation region 122. As a result, light leakage to adjacent charge accumulation regions 122 may be sufficiently reduced, and thus the crosstalk of the backside illuminated image sensor 100 may be significantly reduced.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

1. A backside illuminated image sensor comprising:
a substrate having a frontside surface and a backside surface;
a charge accumulation region disposed in the substrate; and
a light isolation pattern configured to surround at least a portion of the charge accumulation region and comprising a metal material.

2. The backside illuminated image sensor of claim 1, further comprising a light blocking pattern disposed on the backside surface of the substrate and having an opening corresponding to the charge accumulation region.

3. The backside illuminated image sensor of claim 2, wherein the light isolation pattern is made of the same material as the light blocking pattern.

4. The backside illuminated image sensor of claim 2, wherein the light isolation pattern extends from the light blocking pattern toward the frontside surface of the substrate.

5. The backside illuminated image sensor of claim 1, wherein the substrate has a trench extending from the backside surface toward the frontside surface, and the light isolation pattern is disposed in the trench.

6. The backside illuminated image sensor of claim 5, further comprising an anti-reflective layer disposed on the backside surface of the substrate,
wherein the anti-reflective layer comprises first portions disposed between the light isolation pattern and inner surfaces of the trench.

7. The backside illuminated image sensor of claim 1, further comprising:
a field isolation region disposed in a frontside surface portion of the substrate;
an insulating layer disposed on the frontside surface of the substrate and a frontside surface of the field isolation region; and
a bonding pad disposed on a frontside surface of the insulating layer.

8. The backside illuminated image sensor of claim 7, wherein a first through-hole exposing a portion of a backside surface of the field isolation region is formed through the substrate,
an anti-reflective layer is disposed on the backside surface of the substrate, and
the anti-reflective layer comprises a second portion disposed on an inner side surface of the first through-hole and a third portion disposed on the portion of the backside surface of the field isolation region.

9. The backside illuminated image sensor of claim 8, wherein a second bonding pad is disposed on the anti-reflective layer,
a second through-hole is formed through the second bonding pad, the third portion of the anti-reflective layer, the field isolation region, and the insulating layer to expose a portion of a backside surface of the bonding pad, and
a third bonding pad is disposed on the second bonding pad, an inner side surface of the second through-hole, and the portion of the backside surface of the bonding pad.

10. The backside illuminated image sensor of claim 9, wherein a fourth bonding pad is disposed on the third bonding pad,
the third bonding pad is made of the same material as the second bonding pad, and
the fourth bonding pad is made of the same material as the bonding pad.

11. A method of manufacturing a backside illuminated image sensor, the method comprising:
forming a charge accumulation region in a substrate; and
forming a light isolation pattern comprising a metal material in the substrate to surround at least a portion of the charge accumulation region.

12. The method of claim 11, wherein forming the light isolation pattern comprises forming a trench extending from a backside surface of the substrate toward a frontside surface of the substrate and surrounding the at least a portion of the charge accumulation region, and
the light isolation pattern is formed in the trench.

13. The method of claim 12, further comprising forming an anti-reflective layer on the backside surface of the substrate and inner surfaces of the trench,
wherein the light isolation pattern is formed in the trench by forming a metal layer on the anti-reflective layer so that the trench is buried.

14. The method of claim 11, further comprising:
forming a field isolation region in a frontside surface portion of the substrate;
forming an insulating layer on a frontside surface of the substrate and a frontside surface of the field isolation region; and
forming a bonding pad on a frontside surface of the insulating layer.

15. The method of claim 14, further comprising:
forming a first through-hole through the substrate to expose a portion of a backside surface of the field isolation region;
forming an anti-reflective layer on a backside surface of the substrate, an inner side surface of the first through-hole, and the portion of the backside surface of the field isolation region;
forming a first metal layer on the anti-reflective layer;
forming a second through-hole through the first metal layer, the anti-reflective layer, the field isolation region, and the insulating layer to expose a portion of a backside surface of the bonding pad;
forming a second metal layer on the first metal layer, an inner side surface of the second through-hole, and the portion of the backside surface of the bonding pad;
patterning the second metal layer to form a third bonding pad electrically connected to the bonding pad; and
patterning the first metal layer to form a second bonding pad between the anti-reflective layer and the third bonding pad.

16. The method of claim 15, wherein forming the light isolation pattern comprises forming a trench extending from the backside surface of the substrate toward the frontside surface of the substrate and surrounding the at least a portion of the charge accumulation region,
a portion of the anti-reflective layer is formed on inner surfaces of the trench, and
the first metal layer is formed to fill the trench, whereby the light isolation pattern is formed in the trench.

17. The method of claim 16, further comprising forming a light blocking pattern having an opening corresponding to the charge accumulation region on the anti-reflective layer.

18. The method of claim 17, wherein the light blocking pattern is formed on the light isolation pattern by patterning the first metal layer.

19. The method of claim 14, further comprising:
forming a first through-hole through the substrate to expose a portion of a backside surface of the field isolation region;
forming an anti-reflective layer on a backside surface of the substrate, an inner side surface of the first through-hole, and the portion of the backside surface of the field isolation region;
forming a first metal layer on the anti-reflective layer;
forming a second through-hole through the first metal layer, the anti-reflective layer, the field isolation region, and the insulating layer to expose a portion of a backside surface of the bonding pad;
forming a second metal layer on the first metal layer, an inner side surface of the second through-hole, and the portion of the backside surface of the bonding pad;
forming a third metal layer on the second metal layer;
patterning the third metal layer to form a fourth bonding pad on the second metal layer;
patterning the second metal layer to form a third bonding pad on the first metal layer, the inner side surface of the second through-hole, and the portion of the backside surface of the bonding pad; and
patterning the first metal layer to form a second bonding pad between the anti-reflective layer and the third bonding pad.

20. The method of claim 19, wherein the bonding pad is made of the same material as the fourth bonding pad, and the second bonding pad is made of the same material as the third bonding pad.
